(19) United States
(12) Patent Application Publication
(10) Pub. No.: US 2025/0176395 A1
(43) Pub. Date: May 29, 2025

(54) DISPLAY DEVICE

(71) Applicant: Samsung Display Co., LTD., Yongin-si (KR)

(72) Inventors: Soo Hong CHEON, Yongin-si (KR); Kyung Ho PARK, Yongin-si (KR)

(73) Assignee: Samsung Display Co., LTD., Yongin-si (KR)

(21) Appl. No.: 18/736,961

(22) Filed: Jun. 7, 2024

(30) Foreign Application Priority Data
Nov. 27, 2023 (KR) 10-2023-0166749

(51) Int. Cl. H10K 59/38; H10K 59/80

(52) U.S. Cl. CPC H10K 59/38; H10K 59/871

(57) ABSTRACT

A display device includes an emission element layer disposed on a display area of a substrate that also has a non-display area, an opposing substrate facing the substrate, a color filter layer disposed on a surface of an opposing substrate that faces the substrate, in which the color filter layer includes a first color filter, a second color filter and a third color filter that transmit different lights, and a sealing member disposed between the substrate and the opposing substrate and coupling the substrate with the opposing substrate, wherein each of the first color filter, the second color filter and the third color filter includes an opening in the non-display area.

### CROSS REFERENCE TO RELATED APPLICATION(S)

This application claims priority to and the benefit of Korean Patent Application No. 10-2023-0166749 under 35 U.S.C. § 119, filed on Nov. 27, 2023 in the Korean Intellectual Property Office, the disclosure of which is incorporated herein by reference in its entirety.

### BACKGROUND

### 1. Technical Field

The disclosure relates to a display device that includes a color filter layer having openings to prevent moisture permeating through the color filter layer from reaching a sealing member of the display device, thereby preventing delamination defects of the sealing member.

### 2. Description of the Related Art

As the information-oriented society evolves, various demands for display devices are ever increasing. For example, display devices are being employed by a variety of electronic devices such as smart phones, digital cameras, laptop computers, navigation devices, and smart televisions.

Display devices may be flat panel display devices such as a liquid-crystal display device, a field emission display device, and a light-emitting display device. Light-emitting display devices include an organic light-emitting display device including organic light-emitting elements, an inorganic light-emitting display device including inorganic light-emitting elements such as inorganic semiconductor, and a micro light-emitting display device including micro light-emitting elements.

An organic light-emitting element may include two opposing electrodes and an emissive layer interposed therebetween. Electrons and holes supplied from the two electrodes are recombined in the emissive layer to generate excitons, and the generated excitons relax from the excited state to the ground state so that light may be emitted.

An organic light-emitting display device including organic light-emitting elements requires no separate light source such as a backlight unit, and thus it consumes less power and can be made light and thin, as well as exhibiting high-quality characteristics such as wide viewing angle, high luminance and contrast, and fast response speed. Accordingly, an organic light-emitting display device is attracting attention as the next generation display device.

### SUMMARY

Aspects of the disclosure provide a display device that may reduce defects by preventing permeation of moisture from the outside.

It should be noted that objects of the disclosure are not limited to the above-mentioned object; and other objects of the disclosure will be apparent to those skilled in the art from the following descriptions.

According to an aspect of the disclosure, a display device includes an emission element layer disposed on a display area of a substrate, an opposing substrate facing the substrate, a color filter layer disposed on a surface of the opposing substrate and comprising a first color filter, a second color filter and a third color filter that transmit different lights, and a sealing member disposed between the substrate and the opposing substrate and coupling the substrate with the opposing substrate, wherein each of the first color filter, the second color filter and the third color filter includes an opening in the non-display area.

In an embodiment, the first color filter may be disposed on the surface of the opposing substrate, the second color filter may be disposed on a surface of the first color filter, and the third color filter may be disposed on a surface of the second color filter.

In an embodiment, the first color filter may include a first opening, the second color filter may include a second opening, and the third color filter may include a third opening.

In an embodiment, each of the first opening, the second opening and the third opening may have a closed loop shape surrounding the display area.

In an embodiment, the third opening may surround the display area, the second opening may surround the third opening, and the first opening may surround the second opening.

In an embodiment, the first opening may be disposed adjacent to sides of the opposing substrate, the third opening may be disposed adjacent to the display area, and the second opening may be disposed between the first opening and the third opening.

In an embodiment, the first opening, the second opening and the third opening may not overlap one another in a thickness direction of the display device.

In an embodiment, the first opening may expose the surface of the opposing substrate, the second opening may expose a surface of the first color filter and fills the first opening, and the third opening may expose a surface of the second color filter and fills the second opening.

In an embodiment, two of the first opening, the second opening and the third opening may overlap each other in a thickness direction of the display device.

In an embodiment, each of the openings may have a width in a range of about 10 μm to about 20 μm.

In an embodiment, the openings may be spaced apart from one another by about 10 μm to about 100 μm when viewed from top.

In an embodiment, the display device may further include a low-refractive layer disposed on a surface of the color filter layer, a first capping layer disposed on a surface of the low-refractive layer, a wavelength conversion layer disposed on a surface of the first capping layer, a second capping layer disposed on a surface of the wavelength conversion layer, and a spacer layer disposed on a surface of the second capping layer.

In an embodiment, the low-refractive layer may cover one of the openings of the color filter layer.

In an embodiment, the openings of the color filter layer may be disposed between sides of the opposing substrate and the sealing member.

According to an aspect of the disclosure, a display device includes an emission element layer disposed on the display area of a substrate that includes a display area and a non-display area, an opposing substrate facing the substrate, a color filter layer disposed on a surface of an opposing substrate facing the substrate, the color filter layer including a first color filter, a second color filter and a third color filter that transmit different lights, and a sealing member disposed between the substrate and the opposing substrate and coupling the substrate with the opposing substrate, wherein the first color filter includes a first opening, the second color filter includes a second opening, and the third color filter includes a third opening in the non-display area, and wherein the first opening, the second opening and the third opening each surround the display area and do not overlap one another in a thickness direction.

In an embodiment, the first color filter may be a blue color filter, the second color filter may be a red color filter, and the third color filter may be a green color filter, and wherein the first color filter may be disposed on the surface of the opposing substrate, the second color filter may be disposed on a surface of the first color filter, and the third color filter may be disposed on a surface of the second color filter.

In an embodiment, sides of the first color filter, the second color filter and the third color filter may be aligned with a side of the opposing substrate.

In an embodiment, the first opening may be disposed adjacent to a side of the opposing substrate, the third opening may be disposed adjacent to the display area, and the second opening may be disposed between the first opening and the third opening.

In an embodiment, the first opening may be disposed adjacent to a side of the opposing substrate, the second opening may be disposed adjacent to the display area, and the third opening may be disposed between the first opening and the second opening.

In an embodiment, the second opening may be disposed adjacent to a side of the opposing substrate, the third opening may be disposed adjacent to the display area, and the first opening may be disposed between the second opening and the third opening.

According to an embodiment of the disclosure, a plurality of openings may be formed in a color filter layer in a non-display area of a display device, thereby blocking permeation paths of moisture through the color filter layer. Accordingly, it is possible to reduce delamination defects in the color filter layer and thus prevent deterioration of blackness in the non-display area. In addition, it is possible to prevent moisture permeating through the color filter layer from reaching a sealing member, thereby preventing delamination defects of the sealing member.

It should be noted that effects of the disclosure are not limited to those described above and other effects of the disclosure will be apparent to those skilled in the art from the following descriptions.

### BRIEF DESCRIPTION OF THE DRAWINGS

In the drawings, the sizes, thicknesses, ratios, and dimensions of the elements may be exaggerated for ease of description and for clarity. Like reference numbers and/or like reference characters refer to like elements throughout. The above and other aspects and features of the disclosure will become more apparent by describing in detail embodiments thereof with reference to the attached drawings, in which:

FIG. 1 is a schematic plan view of a display device according to an embodiment that is constructed according to principles of the disclosure.

FIG. 2 is a view schematically showing lines included in the display device according to an embodiment.

FIG. 3 is a schematic diagram of an equivalent circuit of a sub-pixel according to an embodiment.

FIG. 4 is a cross-sectional view schematically showing a display device according to an embodiment.

FIG. 5 is a cross-sectional view schematically showing the display area of the display device according to an embodiment.

FIG. 6 is a cross-sectional view schematically showing a display device according to an embodiment.

FIG. 7 is a cross-sectional view schematically showing the non-display area of the display device according to an embodiment.

FIG. 8 is an enlarged view of area A of FIG. 7.

FIG. 9 is a plan view schematically showing a layout of openings of a display device according to an embodiment.

FIG. 10 is a cross-sectional view schematically showing a permeation path of moisture in a display device.

FIGS. 11 to 13 are cross-sectional views schematically showing display devices according to other embodiments.

### DETAILED DESCRIPTION OF THE EMBODIMENTS

The disclosure will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

Each of the features of the various embodiments of the disclosure may be combined or combined with each other, in part or in whole, and technically various interlocking and driving are possible. Each embodiment may be implemented independently of each other or may be implemented together in an association.

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing illustrative features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the illustrative term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some illustrative embodiments may be physically separated into two or more interacting and discrete blocks, units, and/or modules without departing from the scope of the inventive concepts. Further, the blocks, units, and/or modules of some illustrative embodiments may be physically combined into more complex blocks, units, and/or modules without departing from the scope of the inventive concepts.

Hereinafter, embodiments of the disclosure will be described with reference to the accompanying drawings.

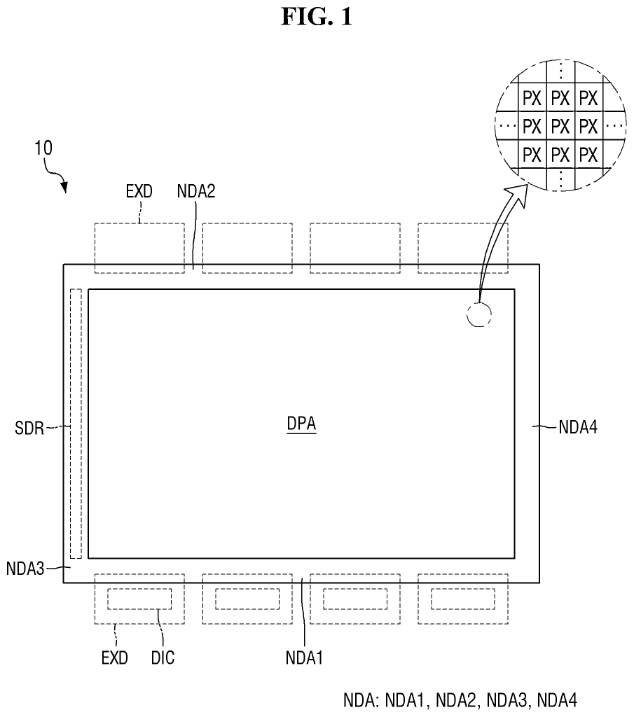

FIG. 1 is a plan view of a display device according to an embodiment.

Referring to FIG. 1, a display device 10 according to an embodiment may be applied to, a smart phone, a mobile phone, a tablet PC, a personal digital assistant (PDA), a portable multimedia player (PMP), a television set, a game machine, a wristwatch-type electronic device, a head-mounted display, a personal computer monitor, a laptop computer, a car navigation system, a car instrument cluster, a digital camera, a camcorder, an outdoor billboard, an electronic billboard, various medical apparatuses, various home appliances such as a refrigerator and a laundry machine, Internet of things (IoT) devices, etc. In the following description, a television is described as an example of the display device 10. TV may have a high resolution or ultra high resolution such as HD, UHD, 4K and 8K.

The display device 10 according to the embodiments may be variously classified by the way in which images are displayed. Examples of the classification of display device 10 may include an organic light-emitting display device (OLED), an inorganic light-emitting display device (inorganic EL), a quantum-dot light-emitting display device (QED), a micro LED display device (micro-LED), a nano LED display device (nano-LED), a plasma display device (PDP), a field emission display device (FED), a cathode ray display device (CRT), a liquid-crystal display device (LCD), an electrophoretic display device (EPD), etc. In the following description, an organic light-emitting display device and an inorganic light-emitting display device will be described as an example of the display device 10, and such light-emitting display devices will be simply referred to as display devices unless it is necessary to discern between them. It is, however, to be understood that the embodiments described herein are not limited to the organic light-emitting display device or an inorganic light-emitting display device, and one of the above-listed display devices or any other display device well known in the art may be employed without departing from the scope of the disclosure.

According to an embodiment, the display device 10 may have a square shape, e.g., a rectangular shape when viewed from the top. When the display device 10 is a television, it is oriented such that the longer sides are positioned in the horizontal direction. It should be understood, however, that the disclosure is not limited thereto. The longer side may be positioned in the vertical direction. As another example, the display device 1 may be installed rotatably so that the longer sides are positioned in the horizontal or vertical direction variably.

The display device 10 may include a display area DPA and a non-display area NDA. The display area DPA may be an active area where images are displayed. The display area DPA may have, but is not limited to, a rectangular shape similar to the general shape of the display device 10 when viewed from the top.

The display area DPA may include pixels PX. The pixels PX may be arranged in a matrix. The shape of each of the pixels PX may be, but is not limited to, a rectangle or a square when viewed from the top. Each of the pixels PX may have a diamond shape having sides inclined with respect to a side of the display device 10. The pixels PX may include different color pixels PX. For example, the pixels PX may include, but is not limited to, a red first color pixel PX, a green second color pixel PX, and a blue third color pixel PX. The color pixels PX may be arranged alternately in a RGB stripe pattern or a PenTile™ matrix.

The non-display area NDA may be disposed around the display area DPA. The non-display area NDA may surround the display area DPA entirely or partially. The display area DPA may have a rectangular shape, and the non-display area NDA may be disposed to be adjacent to the four sides of the display area DPA. The non-display area NDA may form the bezel of the display device 10.

In the non-display areas NDA, a driving circuit or a driving element for driving the display area DPA may be disposed. According to an embodiment, a pad area is disposed on the display substrate of the display device 10 in a first non-display area NDA1 disposed adjacent to a first longer side (the lower side in FIG. 1) of the display device 10 and a second non-display area NDA2 adjacent to a second longer side (the upper side in FIG. 1) of the display device 1. An external device EXD may be mounted on a pad electrode of the pad area. Examples of the external devices EXD may include a connection film, a printed circuit board, a driver chip DIC, a connector, a line connection film, etc. A scan driver SDR formed directly on the display substrate of the display device 10 may be disposed in the third non-display area NDA3 disposed adjacent to a first shorter side of the display device 1 (the left side in FIG. 1). It should be understood, however, that the disclosure is not limited thereto. The scan driver SDR may be disposed on a second shorter side (right side in FIG. 1) of the display device 10.

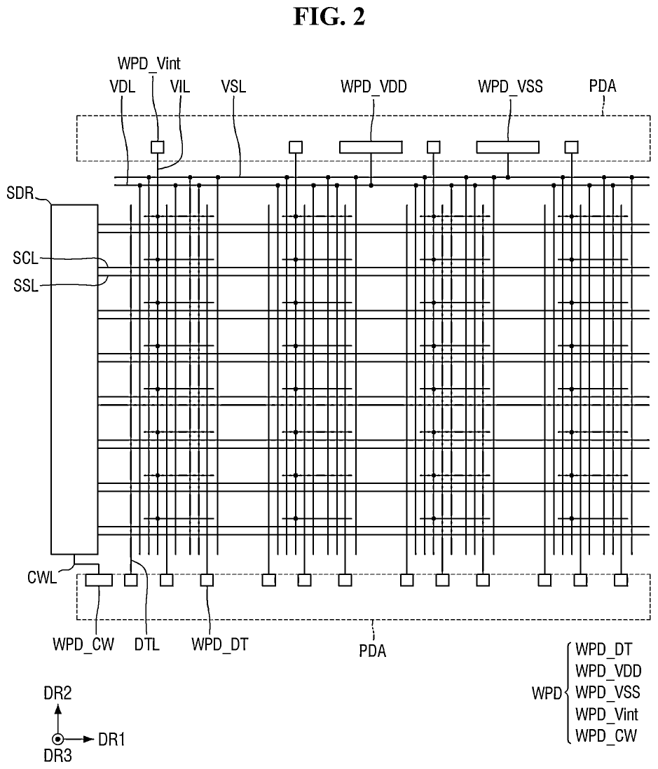

FIG. 2 is a view schematically showing lines included in the display device according to an embodiment.

Referring to FIG. 2, the display device 10 may include lines. The lines may include a scan line SCL, a sensing line SSL, a data line DTL, an initialization voltage line VTL, a first voltage line VDL, a second voltage line VSL, etc. In addition, other lines may be further disposed in the display device 10.

The scan line SCL and the sensing line SSL may be extended in the first direction DR1. The scan line SCL and the sensing line SSL may be connected to a scan driver SDR. The scan driver SDR may include a driving circuit. The scan driver SDR may be disposed on, but is not limited to, one side of the display area DPA in the first direction DR1. The scan driver SDR may be connected to a signal connection line CWL, and at least one end of the signal connection line CWL may form a pad WPD_CW on a pad area PDA in the non-display area to be connected to an external device.

As used herein, when an element is referred to as being “connected” or “coupled” to another element, it can be directly connected or coupled to the element or intervening elements may be present. Such elements may be understood as a single integrated element and thus one portion thereof is connected to another portion. Moreover, when an element is referred to as being “connected” to another element, it may be in direct contact with the element and also electrically connected to the element.

The data line DTL and the initialization voltage line VIL may be extended in a second direction DR2 crossing the first direction DR1. The initialization voltage line VIL may further include branches as well as the portion extended in the second direction DR2. Each of the first voltage line VDL and the second voltage line VSL may also include portions extended in the second direction DR2 and portions connected thereto and extended in the first direction DR1. The first voltage line VDL and the second voltage line VSL may have, but is not limited to, a mesh structure. Each of the pixels PX of the display device 10 may be connected to at least one data line DTL, the initialization voltage line VIL, the first voltage line VDL, and the second voltage line VSL.

The data line DTL, the initialization voltage line VIL, the first voltage line VDL and the second voltage line VSL may be electrically connected to one or more wire pads WPD. The wire pads WPD may be disposed in the pad area PDA. According to an embodiment, a wire pad WPD_DT of the data line DTL (hereinafter referred to as a data pad) may be disposed in the pad area PDA on one side of the display area DPA in the second direction DR2, and a wire pad WPD_Vint of the initialization voltage line VIL (hereinafter referred to as an initialization voltage pad), a wire pad WPD_VDD of the first voltage line VDL (hereinafter referred to as a first power pad), and a wire pad WPD_VSS of the second voltage line VSL (hereinafter referred to as a power pad) may be disposed in the pad area PDA located on the other side of the display area DPA in the second direction DR2. As another example, the data pad WPD_DT, the initialization voltage pad WPD_Vint and the first supply voltage pad WPD_VDD and the second supply voltage pad WPD_VSS may all be disposed in the same area, e.g., in the non-display area NDA on the upper side of the display area DPA. External devices EXD may be mounted on the wire pads WPD. The external devices EXD may be mounted on the wire pads WPD by an anisotropic conductive film, ultrasonic bonding, etc.

Each of the pixels PX or sub-pixels PXn of the display device 10 includes a pixel driving circuit, where n is an integer of 1 to 3. The above-described lines may pass through each of the pixels PX or the periphery thereof to apply a driving signal to the pixel driving circuit. The pixel driving circuit may include transistors and a capacitor. The numbers of transistors and capacitors of each pixel driving circuit may be changed in a variety of ways. According to an embodiment, each of the sub-pixels SPXn of the display device 10 may have a 3T1C structure, i.e., a pixel driving circuit includes three transistors and one capacitor. In the following description, the pixel driving circuit having the 3T1C structure will be described as an example. It is, however, to be understood that the disclosure is not limited thereto. A variety of modified pixel structure may be employed such as a 2T1C structure, a 7T1C structure and a 6T1C structure.

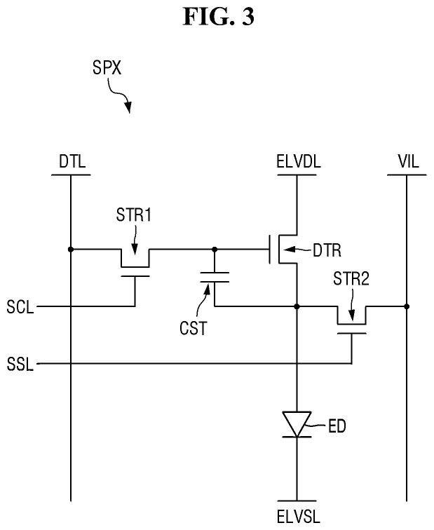

FIG. 3 is a schematic diagram of an equivalent circuit of a sub-pixel according to an embodiment.

Referring to FIG. 3, each of the sub-pixels SPX of the display device 10 according to an embodiment includes three transistors DTR, STR1 and STR2 and one storage capacitor Cst in addition to a light-emitting element ED.

The light-emitting element ED emits light in proportion to the current supplied through the driving transistor DTR. The light-emitting element ED may be implemented as an inorganic light-emitting diode, an organic light-emitting diode, a micro light-emitting diode, a nano light-emitting diode, etc.

The first electrode (i.e., the anode electrode) of the light-emitting diode ED may be connected to the source electrode of the driving transistor DTR, and the second electrode (i.e., the cathode electrode) thereof may be connected to a second supply voltage line ELVSL, from which a low-level voltage (second supply voltage) is applied, lower than a high-level voltage (first supply voltage) of a first supply voltage line ELVDL.

The driving transistor DTR adjusts a current flowing from the first supply voltage line ELVDL from which the first supply voltage is applied to the light-emitting element ED according to the voltage difference between the gate electrode and the source electrode. The gate electrode of the driving transistor DTR may be connected to a first electrode of the first transistor STR1, the source electrode may be connected to a first electrode of the light-emitting element ED, and the drain electrode may be connected to the first supply voltage line ELVDL from which the first supply voltage is applied.

The first transistor STR1 is turned on by a scan signal of a scan line SCL to connect a data line DTL with the gate electrode of the driving transistor DTR. Agate electrode of the first transistor STR1 may be connected to the scan line SCL, the first electrode thereof may be connected to the gate electrode of the driving transistor DTR, and a second electrode thereof may be connected to the data line DTL.

The second transistor STR2 may be turned on by a sensing signal of a sensing signal line SSL to connect the initialization voltage line VIL to the source electrode of the driving transistor DTR. Agate electrode of the second transistor STR2 may be connected to the sensing signal line SSL, a first electrode thereof may be connected to the initialization voltage line VIL, and a second electrode thereof may be connected to the source electrode of the driving transistor DTR.

According to an embodiment, the first electrode of each of the first and second transistors STR1 and STR2 may be a source electrode while the second electrode thereof may be a drain electrode. It is, however, to be understood that the disclosure is not limited thereto. The first electrode of each of the first and second switching transistors STR1 and STR2 may be a drain electrode while the second electrode thereof may be a source electrode.

The capacitor CST may be formed between the gate electrode and the source electrode of the driving transistor DTR. The storage capacitor CST stores a voltage difference between the gate voltage and the source voltage of the driving transistor DTR.

The driving transistor DTR and the first and second transistors STR1 and STR2 may be formed as thin-film transistors. Although FIG. 3 shows that each of the driving transistor DTR and the first and second switching transistors STR1 and STR2 is implemented as an n-type MOSFET (metal oxide semiconductor field effect transistor), it is to be noted that the disclosure is not limited thereto. For example, the driving transistor DTR and the first and second switching transistors STR1 and STR2 may be implemented as p-type MOSFETs, or some of them may be implemented as n-type MOSFETs while the others may be implemented as p-type MOSFETs.

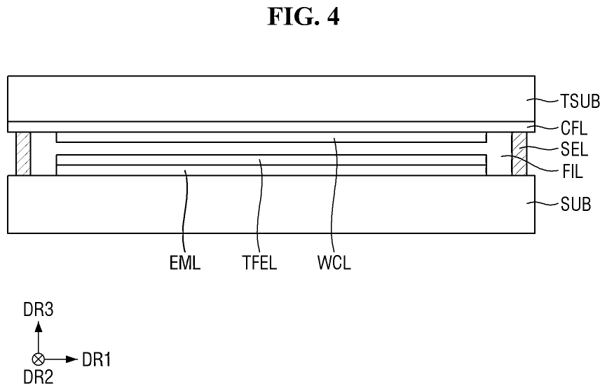

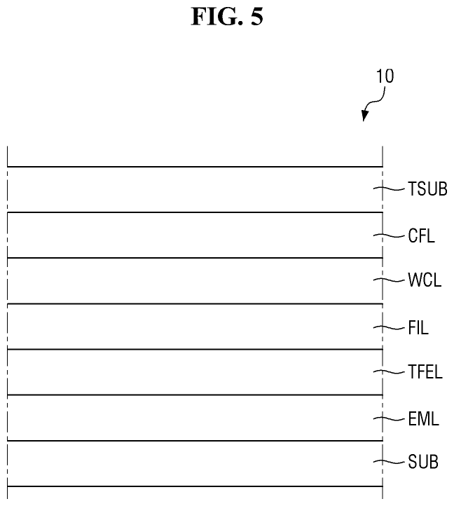

FIG. 4 is a cross-sectional view schematically showing a display device according to an embodiment. FIG. 5 is a cross-sectional view schematically showing the display area of the display device according to the embodiment.

Referring to FIGS. 4 and 5, the display device 10 according to the embodiment may include a substrate SUB, an emission element layer EML, a thin-film transistor layer TFTL, a filling layer FIL, a wavelength conversion layer WCL, a color filter layer CFL, an opposing substrate TSUB and a sealing member SEL.

The substrate SUB may be an insulating substrate. The substrate SUB may include a transparent material. For example, the substrate SUB may include a transparent insulating material such as glass and quartz. The substrate SUB may be a rigid substrate. The substrate SUB is not limited to those described above. The substrate SUB may include a plastic such as polyimide, or may be flexible so that it may be curved, bent, folded or rolled.

The emission element layer EML may be disposed on the substrate SUB. The emission element layer EML may include switching elements and light-emitting elements ED disposed in each sub-pixel. The switching elements may drive light-emitting elements ED so that the light emitting elements ED emit light.

The thin-film encapsulation layer TFEL may be disposed on the emission element layer EML. The thin-film encapsulation layer TFEL may include an organic film disposed between inorganic films and may protect the emission element layer EML from outside moisture and oxygen.

The opposing substrate TSUB facing the substrate SUB may be disposed. The opposing substrate TSUB may encapsulate the emission element layer EML together with the substrate SUB. The opposing substrate TSUB may include a transparent material. For example, the opposing substrate TSUB may include a transparent insulating material such as glass and quartz.

The color filter layer CFL may be disposed on a surface of the opposing substrate TSUB. The color filter layer CFL may filter light incident from the outside to reduce reflection of external light and improve the color characteristics of light emitted through the wavelength conversion layer WCL.

The wavelength conversion layer (WCL) may be disposed on a surface of the color filter layer CFL. The wavelength conversion layer WCL may convert the wavelength of light emitted from the emission element layer EML to emit red light, green light and blue light.

The filling layer FIL may be disposed between the substrate SUB and the opposing substrate TSUB. The filling layer FIL may be used to fill between the substrate SUB and the opposing substrate TSUB to protect the display area of the display device 10.

The substrate SUB and the opposing substrate TSUB may be coupled with each other by the sealing member SEL. The sealing member SEL may seal the emission element layer EML by coupling the substrate SUB with the opposing substrate TSUB. For example, the sealing member may include one or more of the following materials: resin, glass, and rubber. The sealing member SEL may be disposed in the non-display area and may be formed to surround the display area of the display device 10.

Hereinafter, the elements of a display device according to an embodiment will be described in detail with reference to other drawings.

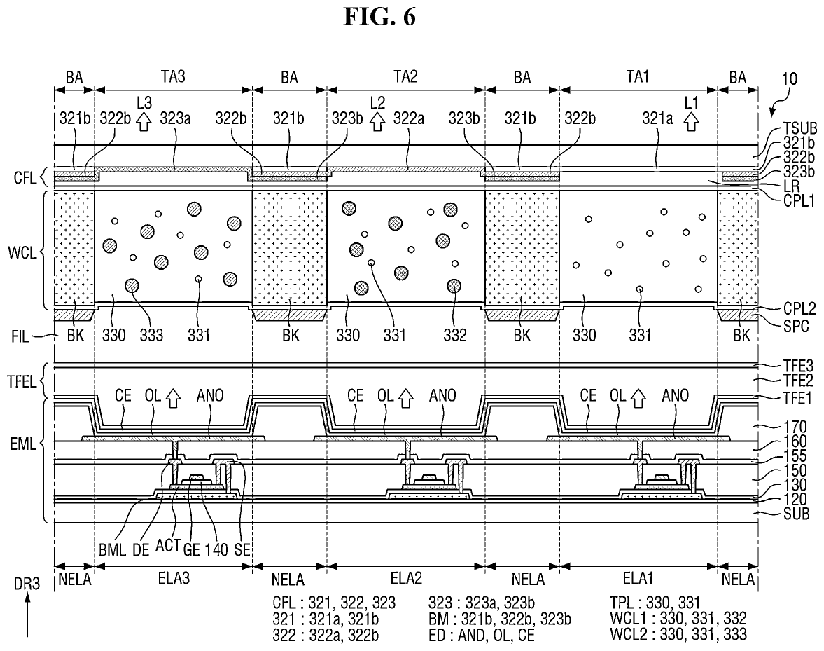

FIG. 6 is a cross-sectional view schematically showing a display device according to an embodiment. FIG. 6 shows a portion of the display area of the display device.

Referring to FIG. 6 in conjunction with FIG. 5, the emission element layer EML may be disposed on the substrate SUB. The emission element layer EML may include a buffer layer 120, a bottom metal layer BML, a first insulating layer 130, a semiconductor layer ACT, a gate electrode GE, a gate insulator GI, a second insulating layer 150, a source electrode SE, a drain electrode DE, a third insulating layer 155, a fourth insulating layer 160, a light-emitting element ED, and a pixel-defining layer 170.

The buffer layer 120 may be disposed on the substrate SUB. The buffer layer 120 may block particles or moisture permeating through the substrate SUB into the elements disposed on the buffer layer 120.

The buffer layer 120 may include, but is not limited to, an inorganic material such as SiO₂, SiNx and SiON, and may be made up of a single layer or multiple layers.

The bottom metal layer BML may be disposed on the buffer layer 120. The bottom metal layer BML may block external light or light existing from light-emitting elements from flowing into the semiconductor layer ACT, which will be described later in more detail. By doing so, it is possible to prevent or reduce the generation of leakage current due to light in a thin-film transistor, which will be described later in more detail.

The bottom metal layer BML may be made of a material that blocks light and has conductivity. According to some embodiments, the bottom metal layer BML may include a single material of metals such as silicon (Ag), nickel (Ni), gold (Au), platinum (Pt), aluminum (Al), copper (Cu), molybdenum (Mo), titanium (Ti) and neodymium (Nd), or an alloy thereof. According to some embodiments, the bottom metal layer BML may be made up of a single layer or multi-layer structure. For example, for the bottom metal layer BML made up of a multilayer structure, the bottom metal layer BML may be, but is not limited to, a stack structure of titanium (Ti)/copper (Cu)/indium tin oxide (ITO) or a stack structure of titanium (Ti)/copper (Cu))/aluminum oxide (Al₂O₃).

According to some embodiments, one or more bottom metal layers BML may be disposed. The number of the bottom metal layer BML may be equal to the number of the semiconductor layers ACT. The bottom metal layers BML may overlap with the semiconductor layers ACT, respectively. According to some embodiments, the width of the bottom metal layer BML may be larger than that of the semiconductor layers ACT.

According to some embodiments, the bottom metal layer BML may be a portion of a data line, a voltage line, a line that electrically connects a thin-film transistor (not shown in the drawings) with the thin-film transistors GE, ACT, DE and SE shown in FIG. 6, etc. According to some embodiments, the bottom metal layer BML may be made of a material having a lower resistance than that of the source electrode SE and the drain electrode DE.

The first insulating layer 130 may be disposed over the bottom metal layer BML. The first insulating layer 130 may electrically insulate the bottom metal layer BML from the semiconductor layer ACT. The first insulating layer 130 may cover the bottom metal layer BML.

The first insulating layer 130 may include, but is not limited to, an inorganic material such as SiO₂, SiNx, SiON, Al₂O₃, TiO₂, Ta₂O, HfO₂ and ZrO₂.

The semiconductor layer ACT may be disposed on the first insulating layer 130. The semiconductor layer ACT may be disposed in each of a first emission area ELA1, a second emission area ELA2 and a third emission area ELA3 in the display area DA. The semiconductor layer ACT may be disposed to overlap with each of the bottom metal layers BML, thereby suppressing generation of photocurrent in the semiconductor layers ACT.

The semiconductor layer ACT may include an oxide semiconductor. According to some embodiments, the semiconductor layer ACT may be made of, but is not limited to, Zn oxide, In—Zn oxide, Ga—In—Zn oxide, etc., as a Zn oxide-based material, and may be an IGZO (In—Ga—Zn—O) semiconductor containing a metal such as indium (In) and gallium (Ga) in ZnO. For example, the semiconductor layer ACT may include amorphous silicon, polysilicon or the like.

The gate electrode GE may be disposed on the semiconductor layer ACT. The gate electrode GE may be disposed in the display area DA to overlap with the semiconductor layer ACT. According to some embodiments, the width of the gate electrode GE may be smaller than the width of the semiconductor layer ACT, but the disclosure is not limited thereto.

The gate electrode GE may include, but is not limited to, at least one of the materials including aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W) and copper (Cu), and may be made up of a single layer or multiple layers, taking into account adhesion to adjacent layers, surface flatness for a layer to be laminated thereon, workability, etc.

The gate insulator 140 may be disposed between the semiconductor layer ACT and the gate electrode GE. The gate insulator 140 may insulate the semiconductor layer ACT from the gate electrode GE. According to some embodiments, the gate insulator 140 may not be made up of a single layer disposed on a surface of the first substrate 110 in the third direction DR3 but may be formed in a partially patterned shape. The width of the gate insulator 140 may be smaller than the width of the semiconductor layer ACT and may be larger than the width of the gate electrode GE. It should be understood, however, that the disclosure is not limited thereto.

The gate insulator 140 may include an inorganic material. For example, the gate insulator 140 may include the inorganic materials listed above as the materials of the first insulating layer 130.

The second insulating layer 150 may be disposed on the gate insulator 140 and cover the semiconductor layer ACT and the gate electrode GE. In some embodiments, the second insulating layer 150 may work as a planarization film that provides a flat surface.

The second insulating layer 150 may include an organic material. According to some embodiments, the second insulating layer 150 may include, but is not limited to, at least one of: photo acryl (PAC), polystyrene, polymethyl methacrylate (PMMA), polyacrylonitrile (PAN), polyamide, polyimide, polyarylether, heterocyclic polymer, parylene, fluorine polymer, epoxy resin, benzocyclobutene series resin, siloxane series resin, and silane resin.

In some embodiments, the second insulating layer 150 may include an inorganic material. For example, the second insulating layer 150 may include the inorganic materials listed above as the materials of the first insulating layer 130.

The source electrode SE and the drain electrode DE may be spaced apart from each other and disposed on the second insulating layer 150. The drain electrode DE and the source electrode SE may be connected to the semiconductor layer ACT through contact holes penetrating the second insulating layer 150. The source electrode SE may be connected to the bottom metal layer BML through the first insulating layer 130 as well as the second insulating layer 150. If the bottom metal layer BML is a portion of a line that transmits a signal or a voltage, the source electrode SE may be connected to and electrically coupled with the bottom metal layer BML and may receive the voltage applied to the line. As another example, if the bottom metal layer BML is a floating pattern rather than a separate line, a voltage applied to the source electrode SE and the like may be transmitted to the bottom metal layer BML.

The source electrode SE and the drain electrode DE may include aluminum (Al), copper (Cu), titanium (Ti), etc., and may be made up of a single layer or multiple layers. In some embodiments, the source electrode SE and the drain electrode DE may have, but is not limited to, a multi-layer structure of Ti/Al/Ti.

The semiconductor layer ACT, the gate electrode GE, the source electrode SE and the drain electrode DE may form a thin-film transistor that is a switching element. According to some embodiments, the thin-film transistor may be disposed in each of the first emission area ELA1, the second emission area ELA2 and the third emission area ELA3. According to some embodiments, a portion of the thin-film transistor may be located in a non-emission area NELA.

The third insulating layer 155 may be disposed on the second insulating layer 150 to cover the thin-film transistor. According to some embodiments, the third insulating layer 155 may be a passivation layer.

According to some embodiments, the third insulating layer 155 may include an inorganic material. For example, the third insulating layer 155 may include the inorganic materials listed above as the materials of the first insulating layer 130.

The fourth insulating layer 160 may be disposed on the third insulating layer 155 to cover the third insulating layer 155. According to some embodiments, the fourth insulating layer 160 may be a passivation film.

The fourth insulating layer 160 may be made of an organic material. According to some embodiments, the fourth insulating layer 160 may include, but is not limited to, an acrylic resin, an epoxy resin, an imide resin, an ester resin, etc., or may include photosensitive organic substances.

Anode electrodes ANO may be located on the fourth insulating layer 160 in the display area DPA.

The anode electrodes ANO may be disposed in the first, second and third emission areas ELA1, ELA2 and ELA3, respectively, and at least a portion of the anode electrodes ANO may be extended to the non-emission area NELA. Anode electrodes ANO may be connected to the drain electrodes DE of the thin-film transistors.

According to some embodiments, the anode electrodes ANO may be reflective electrodes, which may be a metal layer including metal such as Ag, Mg, Al, Pt, Pd, Au, Ni, Nd, Ir and Cr. According to another embodiment, the anode electrodes ANO may further include a metal oxide layer stacked on the metal layer. According to an embodiment, the anode electrodes ANO may have a multi-layer structure, e.g., a two-layer structure of ITO/Ag, Ag/ITO, ITO/Mg or ITO/MgF₂, or a three-layer structure of ITO/Ag/ITO.

The pixel-defining layer 170 may be disposed over the anode electrodes ANO. The pixel-defining layer 170 may define the first emission area ELA1, the second emission area ELA2 and the third emission area ELA3 as openings exposing the anode electrode ANO.

The pixel-defining layer 170 may be in line with light-blocking area BA of the color filter layer CFL in the third direction DR3, which will be described later in more detail. The pixel-defining layer 170 may be in line with the bank BK in the third direction DR3, which will be described later in more detail.

The pixel-defining layer 170 may include an organic insulating material such as polyacrylate resin, epoxy resin, phenolic resin, polyamide resin, polyimide resin, unsaturated polyesters resin, poly phenylen ether resin, poly phenylene sulfide resin, and benzocyclobutene (BCB).

The emissive layer OL may be disposed on the anode electrodes ANO. According to some embodiments, the emissive layer OL may have the shape of a continuous film disposed across the emission areas and the non-emission area NELA. According to some embodiments, the emissive layer OL may be located only in the display area DPA, but the disclosure is not limited thereto. For example, a portion of the emissive layer OL may be further located in the non-display area NDA.

According to some embodiments, the emissive layer OL may include an organic layer containing an organic material. The organic layer includes an organic, emissive layer and may further include hole injection/transport layers and/or electron injection/transport layers as auxiliary layers in some implementations to facilitate emission.

According to the embodiment where the display device 10 is a micro LED display device, a nano LED display device, etc., the emissive layer OL may include an inorganic material such as an inorganic semiconductor.

The cathode electrode CE may be disposed on the emissive layer OL. According to some embodiments, the cathode electrode CE may have the shape of a continuous film disposed on the emissive layer OL and formed across the emission areas ELA1, ELA2 and EL3, and the non-emission area NLA. In other words, the cathode electrode CE may completely cover the emissive layer OL.

The cathode electrode CE may be semi-transmissive or transmissive. If the thickness of the cathode electrode CE ranges from several tens to several hundred angstroms, the cathode electrode CE may be semi-transmissive. According to some embodiments, if the cathode electrode CE is semi-transmissive, it may include Ag, Mg, Cu, Al, Pt, Pd, Au, Ni, Nd, Ir, Cr, Li, Ca, LiF/Ca, LiF/Al, Mo, Ti or a compound or a mixture thereof, e.g., a mixture of Ag and Mg. The cathode electrode CE may contain transparent conductive oxide and may have transparency. According to some embodiments where the cathode electrode CE have the transparency, the cathode electrode CE may be formed of tungsten oxide (WxOx), titanium oxide (TiO₂), indium tin oxide (ITO), indium zinc oxide (IZO), zinc oxide (ZnO), indium tin zinc oxide MgO (magnesium oxide), etc.

The anode electrodes ANO, the emissive layer OL and the cathode electrode CAT may form the light-emitting elements ED. For example, an anode electrode ANO, the emissive layer OL and the cathode electrode CE in the first emission area ELA1 may form a first light-emitting element, an anode electrode ANO, the emissive layer OL and the cathode electrode CE in the second emission area ELA2 may form a second light-emitting element, and an anode electrode ANO, the emissive layer OL and the cathode electrode CE in the third emission area ELA3 may form a third light-emitting element. Each of the first light-emitting element, the second light-emitting element and the third light-emitting element may emit outgoing light. The outgoing light emitted from each of the light-emitting elements ED may have a peak wavelength of in a range of about 440 nm to about 480 nm. For example, the outgoing light LE may be blue light.

The thin-film encapsulation layer TFEL may be disposed on the emission element layer EML. The thin-film encapsulation layer TFEL may be disposed on the cathode electrode CE. The thin-film encapsulation layer TFEL may protect the underlying elements from external foreign matters such as moisture. The thin-film encapsulation layer TFEL may be disposed commonly across the first emission area ELA1, the second emission area ELA2, the third emission area ELA3 and the non-emission area NELA.

The thin-film encapsulation layer TFEL may include a lower inorganic layer TFE1, an organic layer TFE2 and an upper inorganic layer TFE3 sequentially stacked on the cathode electrode CE.

The lower inorganic layer TFE1 may completely cover the cathode electrode CE in the display area DPA, thereby covering the first light-emitting element, the second light-emitting element and the third light-emitting element. The organic layer TFE2 may be disposed on the lower inorganic layer TFE1 and cover the first light-emitting element, the second light-emitting element and the third light-emitting element. The upper inorganic layer TFE3 may be disposed on the organic layer TFE2 and completely cover the organic layer TFE2.

Each of the lower inorganic layer TFE1 and the upper inorganic layer TFE3 may be made of, but is not limited to, at least one of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), lithium fluoride, and the like.

In some embodiments, the organic layer TFE2 may be made of, but is not limited to, acrylic resin, methacrylic resin, polyisoprene, vinyl resin, epoxy resin, urethane resin, cellulose resin and perylene resin.

The opposing substrate TSUB may be disposed over the substrate SUB on which the emission element layer EML and the thin-film encapsulation layer TFEL are disposed. The color filter layer CFL may be disposed on a surface of the opposing substrate TSUB, and the wavelength conversion layer WCL may be disposed on a surface of the color filter layer CFL. The display device 10 may include a low-refractive layer LR and a first capping layer CPL1 disposed between the color filter layer CFL and the wavelength conversion layer WCL, and may include a spacer layer SPC disposed on a surface of the wavelength conversion layer WCL.

The color filter layer CFL may be disposed on the opposite side of the opposing substrate TSUB in the third direction DR3, i.e., between the opposing substrate TSUB and the substrate SUB. The color filter layer CFL may include filtering pattern regions and a light-blocking pattern BM. The light-blocking pattern BM may surround the filtering pattern regions. The filtering pattern of the color filter layer CFL may define transmissive areas, and the light-blocking pattern BM may define a light-blocking area BA.

The color filter layer CFL may include a first color filter 321, a second color filter 322 and a third color filter 323, as shown in FIG. 6. The first color filter 321 may absorb the second light and third light except the first light, the second color filter 322 may absorb the first light and the third light except the second light, and the third color filter 323 may absorb the first light and the second light except the third light. In other words, the first color filter 321 may transmit the first light, the second color filter 322 may transmit the second light, and the third color filter 323 may transmit the third light.

According to some embodiments, the first color filter 321 may be a blue color filter and may include a blue colorant. As used herein, the colorant encompasses a dye as well as a pigment. The first color filter 321 may include a base resin, and the blue colorant may be dispersed in the base resin. According to some embodiments, the second color filter 322 may be a red color filter and may include a red colorant. The second color filter 322 may include a base resin, and the red colorant may be dispersed in the base resin. According to an embodiment, the third color filter 323 may be a green color filter and may include a green colorant. The third color filter 323 may include a base resin, and the green colorant may be dispersed in the base resin.

The first color filter 321 may include a first filtering pattern region 321a and a first light-blocking pattern region 321b surrounding the first filtering pattern region 321a, the second color filter 322 may include a second filtering pattern region 322a and a second light-blocking pattern region 322b surrounding the second filtering pattern region 322a, and the third color filter 323 may include a third filtering pattern region 323a and a third light-blocking pattern region 323b surrounding the third filtering pattern region 323a.

Specifically, the first filtering pattern region 321a of the first color filter 321 may overlap with a first transmissive area TA1, and the first light-blocking pattern region 321b of the first color filter 321 may surround the first filtering pattern region 321a overlapping with the first transmissive area TA1, and may overlap with the light-blocking area BA but not with the second light-transmitting area TA2 or the third light-transmitting area TA1. The second filtering pattern region 322a of the second color filter 322 may overlap with a second transmissive area TA2, and the second light-blocking pattern region 322b of the second color filter 322 may surround the second filtering pattern region 322a overlapping with the second transmissive area TA2, and may overlap with the light-blocking area BA but not with the first transmissive area TA1 or the third transmissive area TA3. The third filtering pattern region 323a of the third color filter 323 may overlap with a third transmissive area TA3, and the third light-blocking pattern region 323b of the third color filter 323 may surround the third filtering pattern region 323a overlapping with the third transmissive area TA3, and may overlap with the light-blocking area BA but not with the first transmissive area TA1 or the second transmissive area TA2. In other words, the filtering pattern region of the color filter layer CFL may include the first filtering pattern region 321a of the first color filter 321, the second filtering pattern region 322a of the second color filter 322 and the third filtering pattern region 323a of the third color filter 323. The light-blocking pattern BM may have a stack structure in which the first light-blocking pattern region 321b of the first color filter 321, the second light-blocking pattern region 322b of the second color filter 322 and the third light-blocking pattern region 323b of the third color filter 323 are stacked on one another.

The first filtering pattern region 321a of the first color filter 321 may function as a blocking filter that blocks red light and green light. Specifically, the first filtering pattern region 321a may selectively transmit the first light (e.g., blue light) and block or absorb the second light (e.g., red light) and the third color light (e.g., green light).

The second filtering pattern region 322a of the second color filter 322 may function as a blocking filter that blocks blue light and green light. Specifically, the second filtering pattern region 322a may selectively transmit the second light (e.g., red light) and block or absorb the first light (e.g., blue light) and the third light (e.g., green light).

The third filtering pattern region 323a of the third color filter 323 may function as a blocking filter that blocks blue light and red light. Specifically, the third filtering pattern region 323a may selectively transmit the third light (e.g., green light) and block or absorb the first light (e.g., blue light) and the second light (e.g., red light).

According to some embodiments, the light-blocking pattern BM may have, but is not limited to, a structure in which the first light-blocking pattern region 321b, the third light-blocking pattern region 323b and the second light-blocking pattern region 322b are sequentially stacked in the third direction DR3. For example, the light-blocking pattern BM may not be formed with the color filters 321, 322 and 323 described above, but may be formed as with a separate organic light-blocking material via coating and exposure processes of the organic light-blocking material. In the following description, the light-blocking pattern have a structure in which the first light-blocking pattern region 321b, the third light-blocking pattern region 323b and the second light-blocking pattern region 322b are sequentially stacked in the third direction DR3 for convenience of illustration. The light-blocking pattern BM may absorb all of the first light, the second light, and the third light through with the above-described configuration.

The low-refractive layer LR may be disposed on a surface of the color filter layer CFL, e.g., on the opposite side in the third direction DR3. The low-refractive layer LR has a lower refractive index than a first light-transmitting member TPL, a second light-transmitting member WCL1 and a third light-transmitting member WCL2, which will be described later, and thus the total reflection of light traveling from the first light-transmitting member TPL, the second light-transmitting member TPL and the third light-transmitting member WCL2 to the low-refractive layer LR is induced, so that the light may be recycled.

The low-refractive layer LR may include an organic material. According to some embodiments, the refractive index of the low-refractive layer LR may be equal to or less than 1.3. With the low-refractive layer LR having the refractive index of 1.3 or less, the total reflection of light may sufficiently occur because the difference in refractive index between the first light-transmitting member TPL, the second light-transmitting member WCL1 and the third light-transmitting member WCL2 is large.

The low-refractive layer LR may compensate for the level differences created by the light-blocking pattern regions 321b, 322b and 323b of the color filter layer CFL to provide a flat surface. Accordingly, the first capping layer CPL1 disposed on the low-refractive layer LR may have a flat surface.

The first capping layer CPL1 may be disposed on a surface of the low-refractive layer LR and cover the low-refractive layer LR. The first capping layer CPL1 may prevent impurities such as moisture and air from permeating into the low-refractive layer LR or the color filter layer CFL from the outside, which may damage or contaminate the low-refractive layer LR and the light-blocking pattern BM and the filtering pattern regions of the color filter layer CFL.

The first capping layer CPL1 may include an inorganic material. According to some embodiments, the first capping layer CPL1 may include, but is not limited to, an inorganic material such as SiO₂, SiNx and SiON, and may be made up of a single layer or multiple layers.

The wavelength conversion layer WCL may be disposed on a surface of the first capping layer CPL1. The wavelength conversion layer WCL may include a bank BK, a first light-transmitting member TPL, a second light-transmitting member WCL1, a third light-transmitting member WCL2 and a second capping layer CPL2.

The bank BK may be disposed on the opposite side of the first capping layer CPL1 in the third direction DR3 in FIG. 6 and may be separately disposed in the second direction DR2 to form space for accommodating the light-transmitting members. For example, the bank BK may define the space where the light-transmitting members are disposed. The bank BK may be in direct contact with the opposite surface of the first capping layer CPL1 in the third direction DR3. The bank BK may surround the light-transmitting members when viewed from the top. The bank BK may overlap with the non-emission area NELA and the light-blocking area BA. The bank BK may not overlap with the emission areas ELA1, ELA2 and ELA3 or the transmissive areas TA1, TA2 and TA3.

According to some embodiments, the bank BK may include, but is not limited to, an organic material that is photocurable or an organic material that is photocurable and includes a light-blocking material.

The first light-transmitting member TPL may be in line with the first transmissive area TA1, the second light-transmitting member WCL1 may be in line with the second transmissive area TA2, and the third light-transmitting member WCL2 may be in line with the third transmissive area TA3. The first light-transmitting member TPL, the second light-transmitting member WCL1 and the third light-transmitting member WCL2 may be referred to as a wavelength conversion layer or a wavelength conversion material layer.

The first light-transmitting member TPL may be disposed in a space defined by the bank BK and may be in line with the first emission area ELA1 and the first transmissive area TA1 in the third direction DR3. The first light-transmitting member TPL may be in direct contact with the first capping layer CPL1 and the bank BK.

The first light-transmitting member TPL may be a light-transmitting pattern that transmits incident light. The first light-transmitting member TPL may transmit the light of the first color emitted from the emission element layer EML as it is. Specifically, the outgoing light provided from the first light-emitting element is blue light as described above, and may transmit the first light-transmitting member TPL and the first filtering pattern region 321a of the first color filter 321 to exit to the outside of the display device 10. In other words, first light L1 that transmits the first transmissive area TA1 and exits to the outside in the first emission area ELA1 may be blue light.

The first light-transmitting member TPL may include a base resin 330 and light scatters 331.

The base resin 330 may be made of an organic material with high light transmittance. According to some embodiments, the base resin 330 may include, but is not limited to, an organic material such as an epoxy resin, an acrylic resin, a cardo resin and an imide resin.

The light scatters 331 may have a refractive index different from that of the base resin 330 and may form an optical interface with the base resin 330. The light scatters 331 may be light-scattering particles. The light scatterers 331 may scatter light in random directions regardless of the direction in which the incident light is incoming, without substantially changing the wavelength of the light transmitting the first transmissive area TA1.

The light scatters 331 may be a material that scatters at least a portion of transmitted light and may include metal oxide particles or organic particles. According to some embodiments, the light scatters 331 may include a metal oxide such as titanium oxide (TiO₂), zirconium oxide (ZrO₂), aluminum oxide (Al₂O₃), indium oxide (In₂O₃), zinc oxide (ZnO) and tin oxide (SnO₂), and may include the organic particles such as an acrylic resin and a urethane resin.

The second light-transmitting member WCL1 may be disposed in a space defined by the bank BK and may be in line with the second emission area ELA2 and the second transmissive area TA2 in the third direction DR3. The second light-transmitting member WCL1 may be in direct contact with the first capping layer CPL1 and the bank BK.

The second light-transmitting member WCL1 may convert or shift the peak wavelength of the incident light into light of another peak wavelength to output the light. The second light-transmitting member WCL1 may convert the light of the first color emitted from the emission element layer EML into light of the second color to output the light. Specifically, the outgoing light provided from the second light-emitting element is blue light as described above, and may transmit the second light-transmitting member WCL1 and the second filtering pattern region 322a of the second color filter 322 to be converted into red light having a peak wavelength in the range of about 610 nm to about 650 nm, so that the light may exit to the outside of the display device 10. In other words, second light L2 that transmits the second transmissive area TA2 and exits to the outside in the second emission area ELA2 may be red light.

The second light-transmitting member WCL1 may include a base resin 330, light scatters 331 dispersed in the base resin 330, and first wavelength shifters 332 dispersed in the base resin 330.

The first wavelength shifters 332 may convert or shift the peak wavelength of the incident light to another peak wavelength. The first wavelength shifters 332 may convert the blue light output from the second light-emitting element into red light having a peak wavelength in the range of about 610 nm to about 650 nm so that the red light exits.

According to some embodiments, the first wavelength shifters 332 may be quantum dots, quantum rods, or phosphor, but the disclosure is not limited thereto. In the following description, the first wavelength shifters 332 are quantum dots for convenience of illustration. The quantum dots may be particulate matter that emits light of a color as electrons transition from the conduction band to the valence band. The quantum dots may be semiconductor nanocrystalline material. The quantum dots have a specific band gap depending on their compositions and size, and may absorb light and emit light having an intrinsic wavelength. Examples of the semiconductor nanocrystals of the quantum dots may include Group IV nanocrystals, Groups II-VI compound nanocrystals, Groups III-V compound nanocrystals, Groups IV-VI nanocrystals, or combinations thereof.

The Group II-VI compounds may be selected from the group consisting of: binary compounds selected from the group consisting of CdSe, CdTe, ZnS, ZnSe, ZnTe, ZnO, HgS, HgSe, HgTe, MgSe, MgS and a mixture thereof, ternary compounds selected from the group consisting of InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and a mixture thereof, and quaternary compounds selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and a mixture thereof.

The Group III-V compounds may be selected from the group consisting of: binary compounds selected from the group consisting of GaN, GaP, GaAs, GaSb, AlN, AlP, AlAs, AlSb, InN, InP, InAs, InSb and a mixture thereof, ternary compounds selected from the group consisting of GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP and a mixture thereof, and quaternary compounds selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and a mixture thereof.

The Group IV-VI compounds may be selected from the group consisting of: binary compounds selected from the group consisting of SnS, SnSe, SnTe, PbS, PbSe, PbTe and a mixture thereof, ternary compounds selected from the group consisting of SnSeS, SnSeTe, SnSTe, PbSeS, PbSeTe, PbSTe, SnPbS, SnPbSe, SnPbTe and a mixture thereof, and quaternary compounds selected from the group consisting of SnPbSSe, SnPbSeTe, SnPbSTe and a mixture thereof. The Group IV elements may be selected from the group consisting of Si, Ge and a mixture thereof. The Group IV compounds may be binary compounds selected from the group consisting of SiC, SiGe and a mixture thereof.

The binary compounds, the ternary compounds or the quaternary compounds may be present in the particles at a uniform concentration, or may be present in the same particles at partially different concentrations. They may have a core/shell structure in which one quantum dot surrounds another quantum dot. At the interface between the core and the shell, the gradient of the concentrate of atoms in the shell may decrease toward the center.

In some embodiments, the quantum dots may have a core-shell structure including a core comprising the nanocrystals and a shell surrounding the core. The shell of the quantum-dots may serve as a protective layer for maintaining the semiconductor properties by preventing chemical denaturation of the core and/or as a charging layer for imparting electrophoretic properties to the quantum dots. The shell may be either a single layer or multiple layers. At the interface between the core and the shell, the gradient of the concentrate of atoms in the shell may decrease toward the center. Examples of the shell of the quantum dot may include an oxide of a metal or a non-metal, a semiconductor compound, a combination thereof, etc.

For example, examples of the metal or non-metal oxide may include, but is not limited to, binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO or ternary compounds such as MgAl₂O₄, CoFe₂O₄, NiFe₂O₄ and CoMn₂O₄.

Examples of the semiconductor compound may include, but is not limited to, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc.

The light output from the first wavelength shifters 332 may have a full width at half maximum (FWHM) of the emission wavelength spectrum of about 45 nm or less, about 40 nm or less, or about 30 nm or less. Accordingly, the color purity and color gamut of the colors displayed by the display device 10 may be further improved. The light output from the first wavelength shifts 332 may travel in different directions regardless of the incidence direction of the incident light. In this manner, the side visibility of the second color displayed in the second transmissive area TA2 may be improved.

A portion of the light output from the second light-emitting element may transmit the second light-transmitting member WCL1 to exit without being converted into red light by the first wavelength shifters 332. The components of the light whose wavelength is not converted by the second light-transmitting member WCL1 and incident on the second filtering pattern region 322a of the second color filter 322 may be blocked by the second filtering pattern region 322a. On the other hand, red light converted by the second light-transmitting member WCL1 may transmit the second filtering pattern region 322a to exit to the outside. For example, the second light L2 exiting to the outside of the display device 10 through the second transmissive area TA2 may be red light.

The third light-transmitting member WCL2 may be disposed in a space defined by the bank BK and may be in line with the third emission area ELA3 and the third transmissive area TA3 in the third direction DR3. The third light-transmitting member WCL2 may be in direct contact with the first capping layer CPL1 and the bank BK.

The third light-transmitting member WCL2 may convert or shift the peak wavelength of the incident light into light of another peak wavelength to output the light. Specifically, the outgoing light provided from the second light-emitting element is blue light as described above, and may transmit the second light-transmitting member WCL1 and the second filtering pattern region 322a of the second color filter 322 to be converted into green light having a peak wavelength in the range of about 510 nm to about 550 nm, so that the light may exit to the outside of the display device 10. In other words, third light L3 that transmits the third transmissive area TA3 and exits to the outside in the third emission area ELA3 may be green light.

The third light-transmitting member WCL1 may include abase resin 330, light scatters 331 dispersed in the base resin 330, and second wavelength shifters 333 dispersed in the base resin 330.

The second wavelength shifters 333 may convert or shift the peak wavelength of the incident light to another peak wavelength. The second wavelength shifters 333 may convert the blue light output from the third light-emitting element into green light having a peak wavelength in the range of about 510 nm to about 550 nm so that the green light exits. According to some embodiments, the second wavelength shifters 333 may be quantum dots, quantum rods, or phosphor, but the disclosure is not limited thereto. The second wavelength shifters 333 of quantum dots may have substantially the same configuration as the first wavelength shifters 332 of quantum dots as described above; and, therefore, the redundant descriptions will be omitted for sake of brevity.

A portion of the light output from the third light-emitting element may transmit the second light-transmitting member WCL1 to exit without being converted into green light by the second wavelength shifters 333. The components of the light whose wavelength is not converted by the third light-transmitting member WCL2 and incident on the third filtering pattern region 323a of the third color filter 323 may be blocked by the third filtering pattern region 323a. On the other hand, green light converted by the third light-transmitting member WCL2 may transmit the third filtering pattern region 323a to exit to the outside. For example, the third light L3 exiting to the outside of the display device 1 through the third transmissive area TA3 may be green light.

The second capping layer CPL2 may be disposed on the bank BK, the first light-transmitting member TPL, the second light-transmitting member WCL1 and the third light-transmitting member WCL2 to prevent impurities such as moisture and air from permeating from the outside to damage or contaminate the first light-transmitting member TPL, the second light-transmitting member WCL1 and the third light-transmitting member WCL2. The second capping layer CPL2 may cover the first light-transmitting member TPL, the second light-transmitting member WCL1 and the third light-transmitting member WCL2.

The spacer layer SPC may be disposed on a surface of the second capping layer CPL2. The spacer layer SPC may maintain a cell gap between the substrate SUB and the opposing substrate TSUB. The spacer layer SPC may surround the light-transmitting members when viewed from the top. The spacer layer SPC may be disposed in line with the non-emission area NELA and the light-blocking area BA. The space layer SPC may not overlap with the emission areas ELA1, ELA2 and ELA3 or the transmissive areas TA1, TA2 and TA3.

According to some embodiments, the space layer SPC may include, but is not limited to, a transparent organic material that is photocurable or an organic material that is photocurable and includes a light-blocking material. According to some embodiments, the spacer SPC may be made of, but is not limited to, at least one of an acrylic resin, a methacrylic resin, polyisoprene, a vinyl resin, an epoxy resin, a urethane resin, a cellulose resin, a perylene resin, etc.

Incidentally, the filling layer FIL may be disposed between the opposing substrate TSUB and the substrate SUB. The filling layer FIL may be interposed between the wavelength conversion layer WCL and the thin-film encapsulation layer TFEL to fill the space between the wavelength conversion layer WCL and the thin-film encapsulation layer TFEL. Specifically, according to some embodiments, the filling layer FIL may be in direct contact with the upper inorganic layer TFE3 of the thin-film encapsulation layer TFEL and the second capping layer CPL2 of the wavelength conversion layer WCL. It should be understood, however, that the disclosure is not limited thereto.

According to some embodiments, the filler layer FIL may be made of a material having an extinction coefficient of substantially zero. The refractive index and the extinction coefficient are correlated, and thus the refractive index decreases with the extinction coefficient. If the refractive index is about 1.7 or less, the extinction coefficient may converge to substantially zero. According to some embodiments, the filler layer FIL may be made of a material having a refractive index of about 1.7 or less. Accordingly, it is possible to prevent or reduce light provided by the self-luminous element from passing through the filler layer FIL and being absorbed. According to some embodiments, the filler layer FIL may be made of an organic material having a refractive index in a range of about 1.4 to about 1.6.

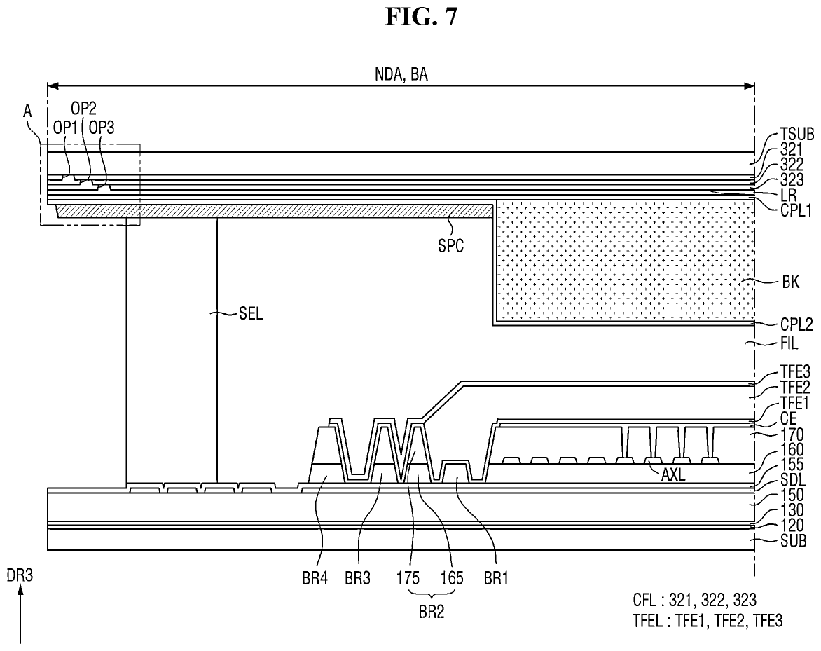

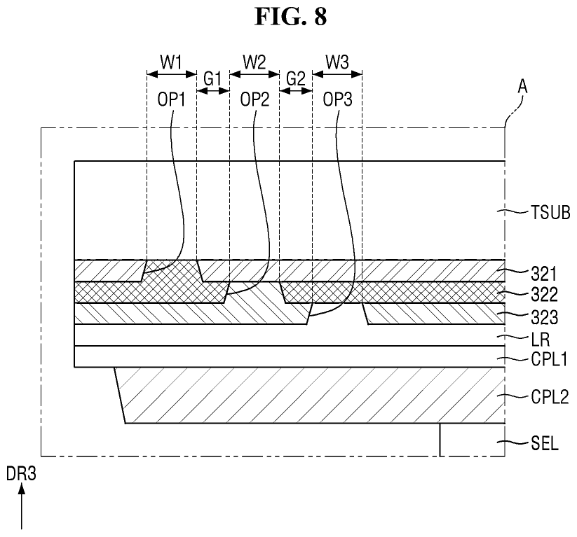

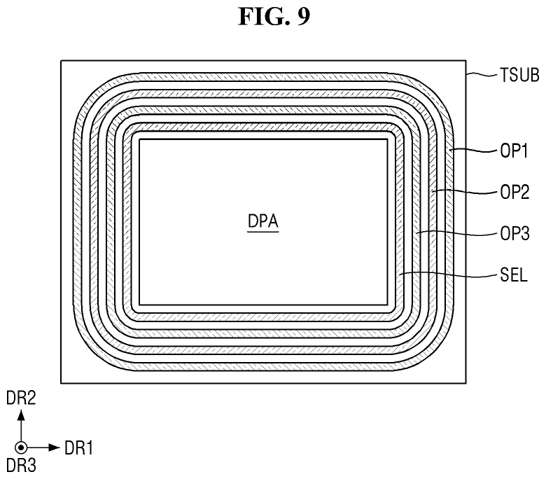

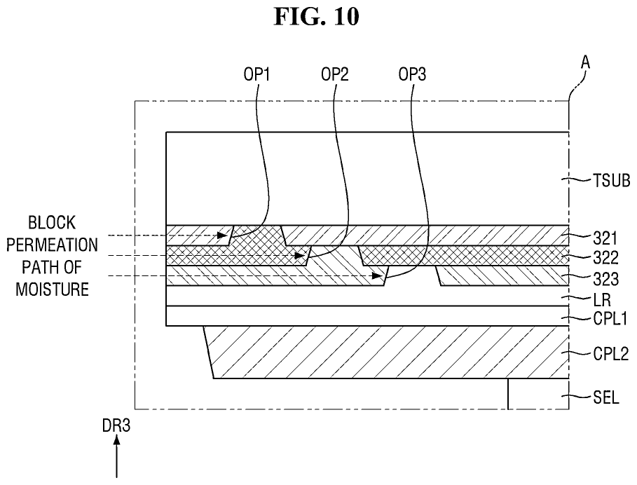

FIG. 7 is a cross-sectional view schematically showing the non-display area of the display device according to the embodiment. FIG. 8 is an enlarged view of area A of FIG. 7. FIG. 9 is a plan view schematically showing a layout of openings of a display device according to an embodiment. FIG. 10 is a cross-sectional view schematically showing a permeation path of moisture in a display device.

Referring to FIGS. 7 to 10 in conjunction with FIG. 6, partition walls BR1, BR2, BR3 and BR4 and a sealing member SEL may be disposed in the non-display area NDA of the display device 10 in addition to layers extended from the display area DPA.

Specifically, the buffer layer 120, the first insulating layer 130, the second insulating layer 150 and the third insulating layer 155 may be disposed on the substrate SUB of the non-display area NDA. The buffer layer 120, the first insulating layer 130, the second insulating layer 150 and the third insulating layer 155 may be extended to the side of the substrate SUB, and the side of the substrate SUB and their sides may be aligned with each other.

A connection line SDL may be disposed between the second insulating layer 150 and the third insulating layer 155. The connection line SDL may be a signal line connected to a thin-film transistor in the display area DPA. According to some embodiments, the connection line SDL may be a gate line or a sensing line. According to some embodiments, the connection line SDL may be a routing line connected to a thin-film transistor in the display area DPA.

The fourth insulating layer 160 may be disposed on the third insulating layer 155. The fourth insulating layer 160 may be extended from the display area DA to the non-display area NDA.

An auxiliary electrode AXL may be disposed on the fourth insulating layer 160. The auxiliary electrode AXL may be electrically connected to a cathode electrode CE extended from the display area DPA. The auxiliary electrode AXL may have the same structure as the anode electrode ANO described above. According to some embodiments, the auxiliary electrode AXL may be a second voltage line that applies a second voltage to the cathode electrode CE. According to some embodiments, the auxiliary electrode AXL may be a routing line that electrically connects a second supply voltage pad with the cathode electrode CE.

A pixel-defining layer 170 covering the auxiliary electrode AXL may be disposed on the fourth insulating layer 160. The pixel-defining layer 170 may be extended from the display area DPA to the non-display area NDA. The pixel-defining layer 170 may include contact holes exposing the underlying auxiliary electrode AXL.

The cathode electrode CE may be disposed on the pixel-defining layer 170. The cathode electrode CE may be extended from the display area DPA to the non-display area NDA. The cathode electrode CE may be electrically connected to the auxiliary electrode AXL through contact holes formed in the fourth insulating layer 160. The contact holes may reduce the contact resistance between the cathode electrode CE and the auxiliary electrode AXL.

Partition walls BR1, BR2, BR3 and BR4 may be disposed on the third insulating layer 155. The partition walls BR1, BR2, BR3 and BR4 may prevent the organic layer TFE2 of the thin-film encapsulation layer TFEL extended from the display area DPA from overflowing.

The partition walls BR1, BR2, BR3 and BR4 may include a first partition wall BR1, a second partition wall BR2, a third partition wall BR3 and a fourth partition wall BR4 arranged sequentially from the display area DPA to the non-display area NDA. The partition walls BR1, BR2, BR3 and BR4 may be spaced apart from one another.

The first partition BR1 may have a single-layer structure. The first partition BR1 may include the same material as the fourth insulating layer 160. The first partition BR1 may be formed via the same mask process as the fourth insulating layer 160.

The second partition BR2, the third partition BR3 and the fourth partition BR4 may each have a multi-layer structure. Each of the second partition wall BR2, the third partition wall BR3 and the fourth partition wall BR4 may include a first layer 165 and a second layer 175 stacked on the first layer 165. The first layer 165 may be disposed directly on the third insulating layer 155 and may include the same material as the fourth insulating layer 160. The first layer 165 may be formed via the same mask process as the fourth insulating layer 160. The second layer 175 may be disposed directly on the first layer 165 and may include the same material as the pixel-defining layer 170. The second layer 175 may be formed via the same mask process as the pixel-defining layer 170.

The thin-film encapsulation layer TFEL may be disposed in the non-display area NDA extended from the display area DPA. The lower inorganic layer TFE1 and the upper inorganic layer TFE3 of the thin-film encapsulation layer TFEL may cover the first partition wall BR1, the second partition wall BR2, the third partition wall BR3, and the fourth partition wall BR4. According to some embodiments, the lower inorganic layer TFE1 and the upper inorganic layer TFE3 completely cover the first partition wall BR1, the second partition wall BR2 and the third partition wall BR3 and may cover a portion of the fourth partition BR4. According to some embodiments, the lower inorganic layer TFE1 and the upper inorganic layer TFE3 completely cover the first partition wall BR1, the second partition wall BR2, the third partition wall BR3 and the fourth partition BR4.

The organic layer TFE2 may be disposed between the lower inorganic layer TFE1 and the upper inorganic layer TFE3 to cover the first and second partition walls BR1 and BR2. According to some embodiments, the organic layer TFE2 may completely cover the first partition wall BR1 and partially cover the second partition wall BR2.

A color filter layer CFL, a low-refractive layer LR and a first capping layer CPL1 may be extended from the display area DPA and disposed on a surface of the opposing substrate TSUB of the non-display area NDA. For example, the first color filter 321, the second color filter 322, the third color filter 323, the low-refractive layer LR and the first capping layer CPL1 may be sequentially stacked. The first color filter 321, the second color filter 322, the third color filter 323, the low-refractive layer LR and the first capping layer CPL1 may be extended to the non-display area NDA and may be aligned with the side of the opposing substrate TSUB. It should be understood, however, that the disclosure is not limited thereto. The first color filter 321, the second color filter 322, the third color filter 323, the low-refractive layer LR and the first capping layer CPL1 may be spaced apart from the side of the opposing substrate TSUB.

The bank BK and the second capping layer CPL2 may be disposed on the first capping layer CPL1. The bank BK and the second capping layer CPL2 may be extended from the display area DPA to the non-display area NDA. The second capping layer CPL2 may cover the bank BK and the first capping layer CPL1.

A spacer layer SPC may be disposed on the second capping layer CPL2. The spacer layer SPC may be extended from the display area DPA to the non-display area NDA. According to some embodiments, the spacer layer SPC may be in a pattern shape spaced apart from the display area DPA.

A filling layer FIL extended from the display area DPA may be disposed between the substrate SUB and the opposing substrate TSUB in the non-display area NDA. The filling layer FIL may be in contact with the upper inorganic layer TFE3 and the third insulating layer 155, and may be in contact with the spacer layer SPC and the second capping layer CPL2. The filling layer FIL may be in contact with the sealing member SEL and may be accommodated in a space defined by the substrate SUB, the opposing substrate TSUB and the sealing member SEL.

The color filter layer CFL disposed in the non-display area NDA may be extended to the side of the opposing substrate TSUB. For example, the sides of the first color filter 321, the second color filter 322 and the third color filter 323 may be aligned with the side of the opposing substrate TSUB. The opposing substrate TSUB on which the color filter layer CFL is formed may be attached to the substrate SUB and then may be scribed. As the opposing substrate TSUB and the color filter layer CFL are scribed together, the side of each of the first color filter 321, the second color filter 322 and the third color filter 323 may be aligned with the side of the opposing substrate TSUB.

The color filter layer CFL may be exposed on the side of the display device 10. The color filter layer CFL may contain an organic material and accordingly may work as a permeation path of moisture from the outside of the display device 10. When moisture permeates from the color filter layer CFL, delamination may occur between the color filter layer CFL and the opposing substrate TSUB, or between the first color filter 321, the second color filter 322 and the third color filter 323. If moisture permeates into the sealing member SEL through the color filter layer CFL, the sealing member SEL may be delaminated.

According to an embodiment, in order to prevent the color filter layer CFL from working as a permeation path of moisture, the color filter layer CFL may include openings OP1, OP2, and OP3.

Specifically, the first color filter 321 may include a first opening OP1, the second color filter 322 may include a second opening OP2, and the third color filter 323 may include a third opening OP3.

The first opening OP1 of the first color filter 321, the second opening OP2 of the second color filter 322 and the third opening OP3 of the third color filter 323 may be located in the non-display area NDA. For example, the first opening OP1, the second opening OP2 and the third opening OP3 may be located outside the display area DA and on the outer side of the sealing member SEL. As the first to third openings OP1, OP2 and OP3 are located on the outer side of the sealing member SEL, it is possible to prevent permeation of moisture into the sealing member SEL through the color filter layer CFL, thereby preventing delamination defects of the sealing member SEL.

In the first opening OP1, the second opening OP2 and the third opening OP3, the color filters 321, 322 and 323 may be disconnected. For example, the first opening OP1 may be formed as a gap where the first color filter 321 is disconnected and separated into parts. The second opening OP2 may be formed as a gap where the second color filter 322 is disconnected and separated into parts. The third opening OP3 may be formed as a gap where the third color filter 323 is disconnected and separated into parts.

The first opening OP1 of the first color filter 321 may expose a surface of the opposing substrate TSUB and may be filled with the second color filter 322. Accordingly, the second color filter 322 may be in contact with the surface of the opposing substrate TSUB through the first opening OP1. The second opening OP2 of the second color filter 322 may expose a surface of the first color filter 321 and may be filled with the third color filter 323. Accordingly, the third color filter 323 may be in contact with the surface of the first color filter 321 through the second opening OP2. The third opening OP3 of the third color filter 323 may expose a surface of the second color filter 322 and may be filled with the low-refractive layer LR. Accordingly, the low-refractive layer LR may be in contact with the surface of the second color filter 322 through the third opening OP3.

As shown in FIG. 9, each of the first opening OP1, the second opening OP2 and the third opening OP3 may have a closed-loop shape when viewed from the top. For example, the third opening OP3 may surround the sealing member SEL and the display area DPA and may have a closed-loop shape. The second opening OP2 may surround the third opening OP3 and may have a closed-loop shape. The first opening OP1 may surround the second opening OP2 and may have a closed-loop shape.

The first opening OP1, the second opening OP2 and the third opening OP3 may be spaced apart from one another when viewed from the top. For example, the first opening OP1, the second opening OP2 and the third opening OP3 may not overlap with one another in the third direction DR3. The first opening OP1, the second opening OP2 and the third opening OP3 may be equally spaced apart from one another. For example, a gap G1 between the first opening OP1 and the second opening OP2 may be equal to a gap G2 between the second opening OP2 and the third opening OP3. According to some embodiments, the gaps between two of the first opening OP1, the second opening OP2 and the third opening OP3 may be different. For example, the gap G1 between the first opening OP1 and the second opening OP2 may be greater than or less than the gap G2 between the second opening OP2 and the third opening OP3.

According to an embodiment, the gap GI between the first opening OP1 and the second opening OP2 and the gap G2 between the second opening OP2 and the third opening OP3 may be in a range of about 10 μm to about 100 μm. If the gap G1 between the first opening OP1 and the second opening OP2 and the gap G2 between the second opening OP2 and the third opening OP3 are equal to or greater than 10 μm, it is easy to form the first to third openings OP1, OP2 and OP3 such that they are spaced apart from one another. If the gap G1 between the first opening OP1 and the second opening OP2 and the gap G2 between the second opening OP2 and the third opening OP3 are equal to or less than about 100 μm, it is possible to prevent the width of the non-display area NDA from increasing.

The first opening OP1 may be closest to the side of the opposing substrate TSUB and furthest from the display area DPA. The second opening OP2 may be disposed between the first opening OP1 and the display area DPA, between the first opening OP1 and the third opening OP3, or between the first opening OP1 and the sealing member SEL. The third opening OP3 may be located between the second opening OP2 and the display area DPA or between the second opening OP2 and the sealing member SEL.

The first opening OP1, the second opening OP2 and the third opening OP3 have the widths W1, W2 and W3, respectively, in the first direction DR1. The widths W1, W2 and W3 of the first opening OP1, the second opening OP2 and the third opening OP3 may be all equal. According to some embodiments, the widths W1, W2 and W3 of the first opening OP1, the second opening OP2 and the third opening OP3 may be different from one another. In some embodiments, the width W1 of the first opening OP1 may be greater than the width W2 of the second opening OP2, and the width W2 of the second opening OP2 may be greater than the width W3 of the third opening OP3. According to some embodiments, the width W1 of the first opening OP1 may be smaller than the width W2 of the second opening OP2, and the width W2 of the second opening OP2 may be smaller than the width W3 of the third opening OP3.

The widths W1, W2 and W3 of the first opening OP1, the second opening OP2 and the third opening OP3 may be in a range of about 10 μm to 20 μm. With widths W1, W2 and W3 of the first opening OP1, the second opening OP2 and the third opening OP3 of about 10 μm or more, it is possible to cut permeation paths of moisture by separating the color filters. With widths W1, W2 and W3 of the first opening OP1, the second opening OP2 and the third opening OP3 of about 20 μm or less, it is possible to avoid deterioration of the light-blocking function of the color filter layer CFL in the non-display area NDA.

As shown in FIG. 10, the first color filter 321, the second color filter 322 and the third color filter 323 have openings OP1, OP2 and OP3, respectively, and may block permeation paths of moisture. For example, a permeation path of moisture through the first color filter 321 may be blocked at the first opening OP1, a permeation path of moisture through the second color filter 322 may be blocked at the second opening OP2, and a permeation path of moisture through the third color filter 323 may be blocked at the third opening OP3. Accordingly, it is possible to prevent the color filter layer CFL from working as permeation paths of moisture, thereby suppressing delamination between the color filter layer CFL and the sealing member SEL.

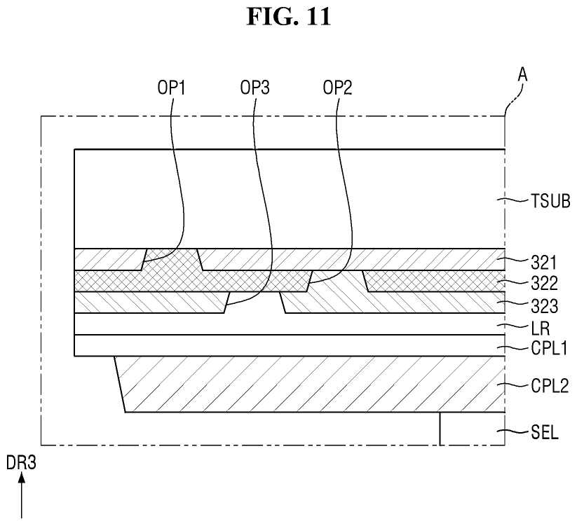

FIGS. 11 to 13 are cross-sectional views schematically showing display devices according to other embodiments. FIGS. 11 to 13 show area A of FIG. 7.

The embodiment of FIGS. 11 to 13 is different from the above-described embodiment in that a layout of a first opening OP1 of a first color filter 321, a second opening OP2 of a second color filter 322 and a third opening OP3 of a third color filter 323 are different. The following description will focus on the difference and the redundant description will be omitted for sake of brevity.

Referring to FIG. 11, the third opening OP3 of the third color filter 323 may be located between the first opening OP1 of the first color filter 321 and the second opening OP2 of the second color filter 322.

The second opening OP2 may surround the sealing member SEL and the display area DPA. The third opening OP3 may surround the second opening OP2, and the first opening OP1 may surround the third opening OP3.

The first opening OP1 may be closest to the side of the opposing substrate TSUB and furthest from the display area DPA. The third opening OP3 may be located between the first opening OP1 and the display area DPA, between the first opening OP1 and the third opening OP3, or between the first opening OP1 and the sealing member SEL. The second opening OP2 may be located between the third opening OP3 and the display area DPA or between the third opening OP2 and the sealing member SEL.

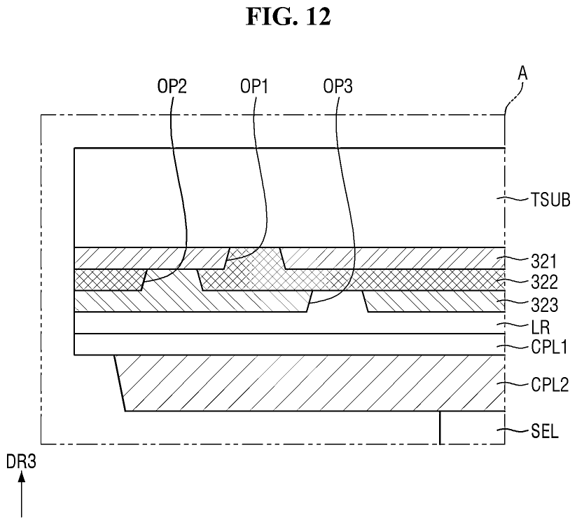

Referring to FIG. 12, a first opening OP1 of a first color filter 321 may be located between a second opening OP2 of a second color filter 322 and a third opening OP3 of a third color filter 323, unlike FIG. 11.

The third opening OP3 may surround the sealing member SEL and the display area DPA. The first opening OP1 may surround the third opening OP3, and the second opening OP2 may surround the first opening OP1.

The second opening OP2 may be closest to the side of the opposing substrate TSUB and furthest from the display area DPA. The first opening OP1 may be located between the second opening OP2 and the display area DPA, between the second opening OP2 and the third opening OP3, or between the second opening OP2 and the sealing member SEL. The third opening OP3 may be located between the first opening OP1 and the display area DPA or between the first opening OP1 and the sealing member SEL.

It should be understood, however, that the disclosure is not limited thereto. The first opening OP1 of the first color filter 321 may be disposed closest to the sealing member SEL, the second opening OP2 of the second color filter 322 may be disposed closest to the side of the opposing substrate TSUB, and the third opening OP3 of the third color filter 323 may be disposed between the first opening OP1 and the second opening OP2 when viewed from the top.

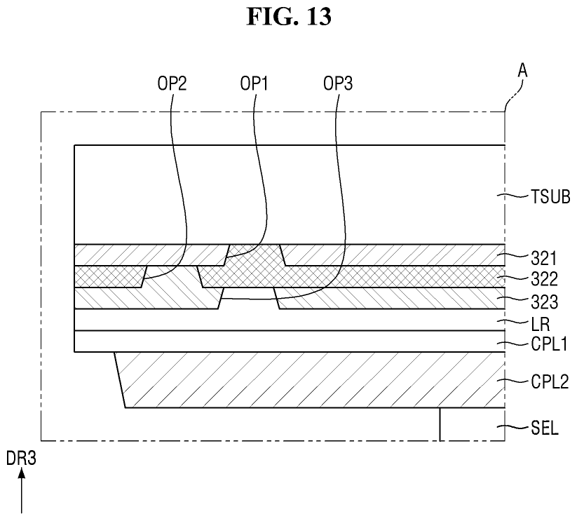

Unlike FIGS. 11 and 12, referring to FIG. 13, at least two of the first opening OP1 of the first color filter 321, the second opening OP2 of the second color filter 322 and the third opening OP3 of the third color filter 323 may overlap one another in the third direction DR3. For example, the first opening OP1 and the third opening OP3 may overlap each other in the third direction DR3. The first opening OP1 and the third opening OP3 may be aligned and coincide with each other when viewed from the top. It should be understood, however, that the disclosure is not limited thereto. The second opening OP2 and the third opening OP3 may overlap each other in the third direction.

According to the embodiment of the disclosure, the first opening OP1 may overlap with the third opening OP3, and the first opening OP1 and the third opening OP3 may not overlap with the second opening OP2. For example, two of the first to third openings OP1, OP2 and OP3 may overlap each other while the other opening may not overlap with the two openings.

As described above, the display device 10 according to the embodiment includes openings OP1, OP2 and OP3 in the color filter layer CFL, thereby blocking permeation paths of moisture through the color filter layer CFL. In this manner, it is possible to suppress delamination defects of the color filter layer CFL and to prevent the blackness of the non-display area NDA from being deteriorated. It is possible to prevent deterioration of the encapsulation performance of the display device 10 by reducing delamination defects of the sealing member SEL.

In concluding the detailed description, those skilled in the art will appreciate that many variations and modifications may be made to the embodiments without substantially departing from the principles and spirit and scope of the invention. Therefore, the disclosed embodiments are used in a generic and descriptive sense only and not for purposes of limitation.

What is claimed is:

1. A display device comprising:
an emission element layer disposed on a display area of a substrate that has the display area and a non-display area;
an opposing substrate facing the substrate;
a color filter layer disposed on a surface of an opposing substrate facing the substrate, the color filter layer including a first color filter, a second color filter and a third color filter that transmit different lights; and
a sealing member disposed between the substrate and the opposing substrate and coupling the substrate with the opposing substrate,
wherein each of the first color filter, the second color filter and the third color filter includes an opening in the non-display area.

2. The display device of claim 1, wherein the first color filter is disposed on the surface of the opposing substrate, the second color filter is disposed on a surface of the first color filter, and the third color filter is disposed on a surface of the second color filter.

3. The display device of claim 1, wherein the first color filter includes a first opening, the second color filter includes a second opening, and the third color filter includes a third opening.

4. The display device of claim 3, wherein each of the first opening, the second opening and the third opening has a closed loop shape surrounding the display area.

5. The display device of claim 4, wherein
the third opening surrounds the display area,
the second opening surrounds the third opening, and
the first opening surrounds the second opening.

6. The display device of claim 4, wherein
the first opening is disposed adjacent to sides of the opposing substrate,
the third opening is disposed adjacent to the display area, and
the second opening is disposed between the first opening and the third opening.

7. The display device of claim 3, wherein the first opening, the second opening and the third opening do not overlap one another in a thickness direction of the display device.

8. The display device of claim 7, wherein
the first opening exposes the surface of the opposing substrate,
the second opening exposes a surface of the first color filter and fills the first opening, and
the third opening exposes a surface of the second color filter and fills the second opening.

9. The display device of claim 3, wherein two of the first opening, the second opening and the third opening overlap each other in a thickness direction of the display device.

10. The display device of claim 1, wherein each of the openings has a width in a range of about 10 μm to about 20 μm.

11. The display device of claim 1, wherein the openings are spaced apart from one another by about 10 μm to about 100 μm when viewed from top.

12. The display device of claim 1, further comprising:
a low-refractive layer disposed on a surface of the color filter layer;
a first capping layer disposed on a surface of the low-refractive layer;
a wavelength conversion layer disposed on a surface of the first capping layer;
a second capping layer disposed on a surface of the wavelength conversion layer; and
a spacer layer disposed on a surface of the second capping layer.

13. The display device of claim 12, wherein the low-refractive layer covers one of the openings of the color filter layer.

14. The display device of claim 1, wherein the openings of the color filter layer are disposed between sides of the opposing substrate and the sealing member.

15. A display device comprising:
an emission element layer disposed on a display area of a substrate that has the display area and a non-display area;
a color filter layer disposed on a surface of an opposing substrate facing the substrate, the color filter layer including a first color filter, a second color filter and a third color filter that transmit different lights; and
a sealing member disposed between the substrate and the opposing substrate and coupling the substrate with the opposing substrate, wherein
the first color filter includes a first opening, the second color filter includes a second opening, and the third color filter includes a third opening in the non-display area, and
the first opening, the second opening and the third opening each surround the display area and do not overlap one another in a thickness direction.

16. The display device of claim 15, wherein
the first color filter is a blue color filter, the second color filter is a red color filter, and the third color filter is a green color filter, and
the first color filter is disposed on the surface of the opposing substrate, the second color filter is disposed on a surface of the first color filter, and the third color filter is disposed on a surface of the second color filter.

17. The display device of claim 15, wherein sides of the first color filter, the second color filter and the third color filter are aligned with a side of the opposing substrate.

18. The display device of claim 15, wherein the first opening is disposed adjacent to a side of the opposing substrate, the third opening is disposed adjacent to the display area, and the second opening is disposed between the first opening and the third opening.

19. The display device of claim 15, wherein the first opening is disposed adjacent to a side of the opposing substrate, the second opening is disposed adjacent to the display area, and the third opening is disposed between the first opening and the second opening.

20. The display device of claim 15, wherein the second opening is disposed adjacent to a side of the opposing substrate, the third opening is disposed adjacent to the display area, and the first opening is disposed between the second opening and the third opening.
